(19) United States
(12) Patent Application Publication
(10) Pub. No.: US 2026/0107553 A1
(43) Pub. Date: Apr. 16, 2026

(54) SPLIT METAL GATE FORMATION PROCESS AND METHOD

(71) Applicant: Taiwan Semiconductor Manufacturing Co., Ltd., Hsinchu (TW)

(72) Inventors: Kai-Chieh Yang, New Taipei (TW); Szu-Hua Chen, Tainan (TW); Wei-Yen Woon, Taoyuan (TW); Szuya Liao, Zhubei (TW)

(21) Appl. No.: 19/187,107

(22) Filed: Apr. 23, 2025

Related U.S. Application Data
(60) Provisional application No. 63/707,070, filed on Oct. 14, 2024.

(51) Int. Cl. H10D 84/01; H10D 64/01; H10D 84/83

(52) U.S. Cl. CPC H10D 84/014; H10D 64/017; H10D 84/832

(57) ABSTRACT

In an embodiment, a method includes forming a multi-layer stack including alternating semiconductor nanostructures and dummy nanostructures, forming lower source/drain regions, where lower semiconductor nanostructures of the semiconductor nanostructures extend between the lower source/drain regions, forming upper source/drain regions over the lower source/drain regions, where upper semiconductor nanostructures of the semiconductor nanostructures extend between the upper source/drain regions, removing the dummy nanostructures to form first openings between the lower semiconductor nanostructures, and second openings between the upper semiconductor nanostructures, forming a gate dielectric layer around the lower semiconductor nanostructures and the upper semiconductor nanostructures, forming a lower gate electrode around the lower semiconductor nanostructures and in the first openings, selectively depositing a dummy layer over top surfaces of the lower gate electrode, the dummy layer including a first polymer, and forming an upper gate electrode around the upper semiconductor nanostructures and in the second openings.

### CROSS-REFERENCE TO RELATED APPLICATIONS

This application claims priority to U.S. Application No. 63/707,070, filed on October 14, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-22B are views of intermediate stages in the manufacturing of CFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor device that includes CFETs may be formed. A CFET includes a lower nanostructure-FET and an upper nanostructure-FET disposed over the lower nanostructure-FET. Forming the semiconductor device may include forming upper channel regions of upper nanostructure-FETs and lower channel regions of lower nanostructure-FETs, the upper channel regions and the lower channel regions being disposed over a fin. A gate dielectric layer is formed around the upper channel regions and the lower channel regions, and over the fin. Lower gate electrodes are then formed over the gate dielectric layer and around the lower channel regions. A dummy layer may be selectively deposited on exposed surfaces (e.g., top surfaces) of the lower gate electrodes such that the dummy layer is not formed on surfaces of the gate dielectric layer disposed around the upper channel regions. The dummy layer may comprise an anionic polymer such as polyacrylic acid (PAA), polyvinyl alcohol (PVA), or the like. The dummy layer may be formed using a spin-on coating process, or the like, that is used to deposit a solution having an anionic polymer concentration that is in a range from 10 percent to 40 percent by weight. In some embodiments, the dummy layer may also comprise a nonionic polymer, such as polyacrylamide, polyethylene glycol (polyethylene oxide), polystyrene sulfonate, polyvinyl pyrrolidone, or the like. After the formation of the dummy layer, a first metal-containing material layer (which may also be referred to as a first conductive layer) may be selectively formed over the gate dielectric layer and around the upper channel regions, such that the first metal-containing layer is not formed on surfaces (e.g., top surfaces) of the dummy layer. A second metal-containing material layer (which may also be referred to as a second conductive layer) is then selectively formed around the first metal-containing layer and around the upper channel regions, such that the second metal-containing layer is not formed on surfaces (e.g., top surfaces) of the dummy layer. The dummy layer may then be removed using water or a water-based solution. An isolation layer (e.g., comprising a dielectric material) is then formed over the lower gate electrodes (e.g., on top surfaces of the lower gate electrodes). Upper gate electrodes are then formed over the isolation layer, and on surfaces of the second metal-containing layer and the first metal-containing layer around the upper channel regions. The isolation layer may electrically isolate the lower gate electrodes and the upper gate electrodes from each other, and the combination of the lower gate electrodes and the upper gate electrodes may be referred to subsequently as a split metal gate.

Advantageous features of one or more embodiments disclosed herein may allow for the formation of the isolation layer that is disposed between the lower gate electrodes and the upper gate electrodes, and that electrically isolates the lower gate electrodes from the upper gate electrodes. The dummy layer (e.g., comprising an anionic polymer such as polyacrylic acid (PAA), polyvinyl alcohol (PVA), or the like) is selectively formed on the exposed surfaces (e.g., the top surfaces) of the lower gate electrodes such that the dummy layer is not formed on surfaces of the gate dielectric layer disposed around the upper channel regions. This allows for the subsequent selective formation of the first metal-containing layer and the second metal-containing layer on the surfaces of the gate dielectric layer and around the upper channel regions, such that the first metal-containing layer and the second metal-containing layer are not formed on surfaces (e.g., top surfaces) of the dummy layer. The dummy layer may then be removed using water or a water-based solution, and the isolation layer (e.g., comprising a dielectric material) is then formed over the lower gate electrodes. Upper gate electrodes may then be formed over the isolation layer, and on surfaces of the second metal-containing layer and the first metal-containing layer around the upper channel regions. As a result, the number of patterning steps (e.g., including masking and etching processes) that are used to form the isolation layer that is disposed between the upper gate electrodes and the lower gate electrodes can be reduced. In addition, the water-based removal process of the dummy layer may reduce a risk of damage to underlying device structures compared to other etching processes (e.g., dry etching processes). This may lead to improved device reliability, improved manufacturing yields, and the simplifying of the overall device fabrication process.

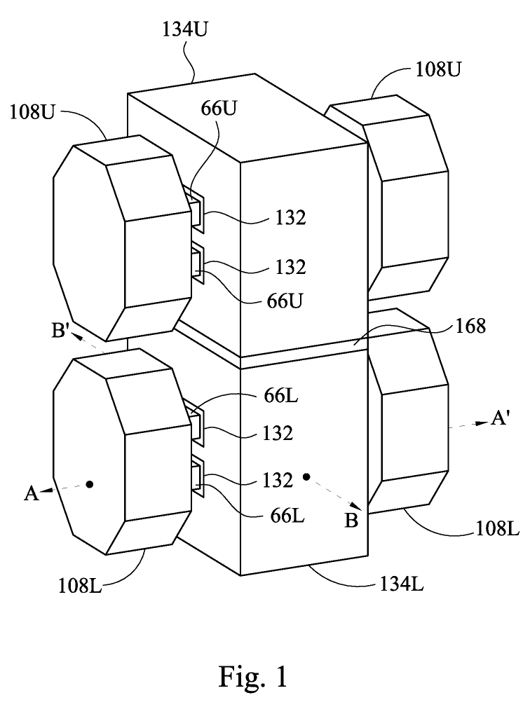

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

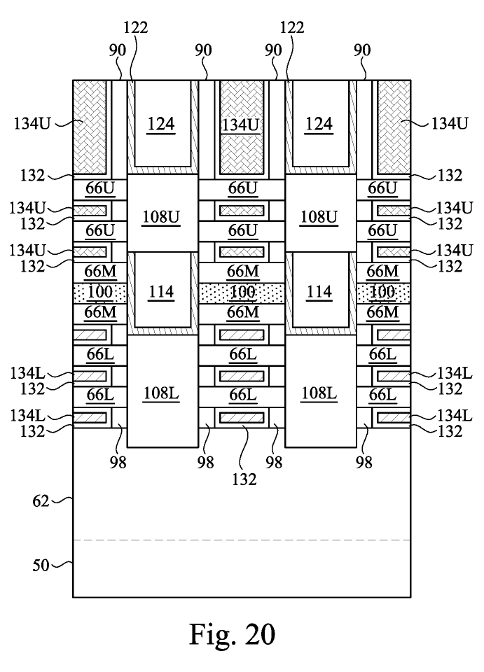

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIG. 20) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer 168 disposed between the lower gate electrode 134L and the upper gate electrode 134U. Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIG. 1, see FIG. 20). The isolation features between channel regions, gates, and source/drain regions allow for vertically stacked transistors, thereby improving device density. Because of the vertically stacked nature of CFETs, the schematic may also be referred to as stacked transistors or folding transistors.

FIG. 1 further illustrates reference cross-sections that are used in later figures. Cross-section A-A' is parallel to a longitudinal axis of the semiconductor nanostructures 66 of a CFET and in a direction of, for example, a current flow between the source/drain regions 108 of the CFET. Cross-section B-B' is perpendicular to cross-section A-A' and along a longitudinal axis of a gate electrode 134 of a CFET. Subsequent figures refer to these reference cross-sections for clarity.

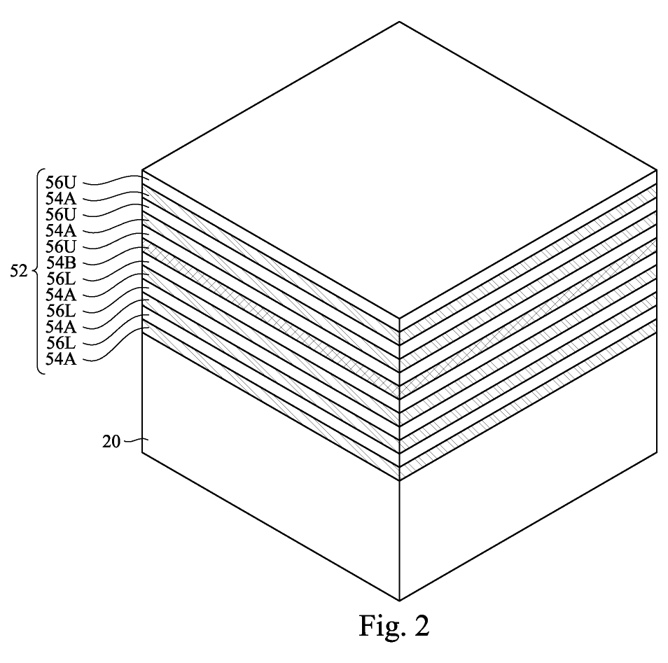

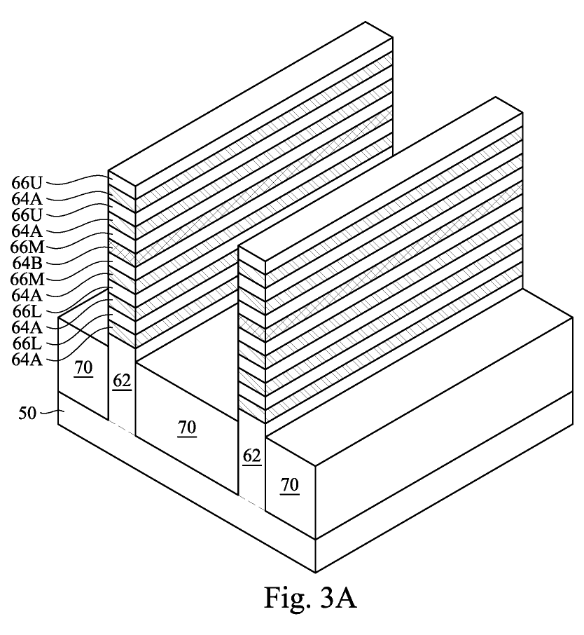

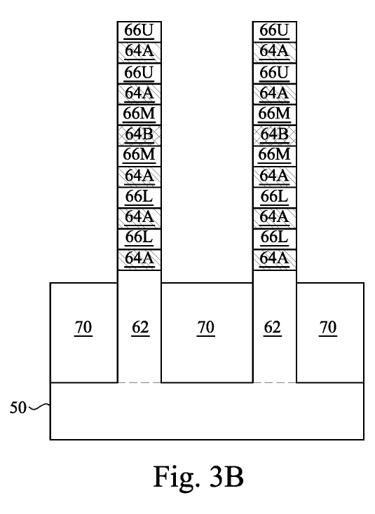

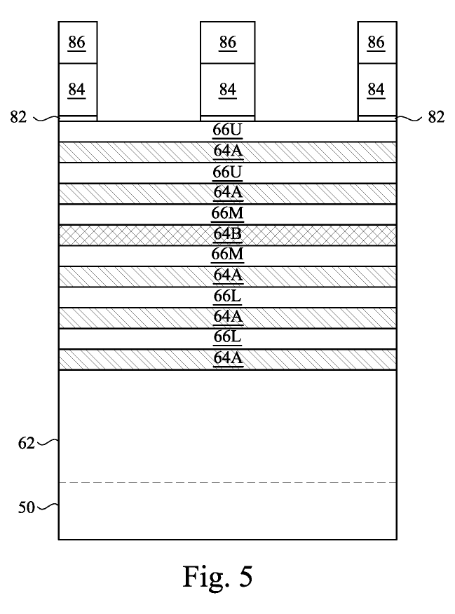

FIGS. 2-22B are views of intermediate stages in the manufacturing of CFETs, in accordance with some embodiments. FIGS. 2, 3A, and 4 are three-dimensional views showing a similar three-dimensional view as FIG. 1. FIGS. 5, 6, 7, 8, 9, 10A, 11A, 20, 21, and 22A illustrate cross-sectional views along a similar cross-section as reference cross-section A-A' in FIG. 1. FIGS. 3B, 10B, 11B, 12, 13A, 13B 14A, 14B, 14C, 15, 16, 17, 18, 19, and 22B illustrate a cross-sectional view along a similar cross-section as reference cross-section B-B' in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A and the second dummy layer 54B may be formed of a first semiconductor material. The first semiconductor material may be selected from the candidate semiconductor materials of the substrate 50. In some embodiments, the dummy layers 54 (e.g., the first dummy layers 54A and the second dummy layer 54B) are formed of or comprise silicon germanium, and the second dummy layer 54B may be formed of germanium or silicon germanium with a higher germanium atomic percentage than the first dummy layers 54A. The first dummy layers 54A and the second dummy layer 54B have a high etching selectivity to one another, such that the second dummy layer 54B may be removed at a faster rate than the first dummy layers 54A in subsequent processing. The semiconductor layers 56 (including the lower semiconductor layers 56L and upper semiconductor layers 56U) are formed of a second semiconductor material that is different from the first semiconductor material. The second semiconductor material may be selected from the candidate semiconductor materials of the substrate 50. In some embodiments, the semiconductor layers 56 are formed of silicon. The semiconductor layers 56 and the dummy layers 54 have a high etching selectivity to one another, such that the dummy layers 54 (e.g., the first dummy layers 54A and the second dummy layer 54B) may be removed at a faster rate than the semiconductor layers 56 (e.g., the lower semiconductor layers 56L and the upper semiconductor layers 56U) in subsequent processing.

In FIGS. 3A and 3B, fins 62 are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape.

Further, isolation regions 70 are formed over the substrate 50 and between adjacent semiconductor fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) may be recessed such that upper portions of the semiconductor fins 62 and the nanostructures 64, 66 extend higher than the isolation regions 70.

The previously described process is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may comprise the previously described alternating semiconductor materials, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

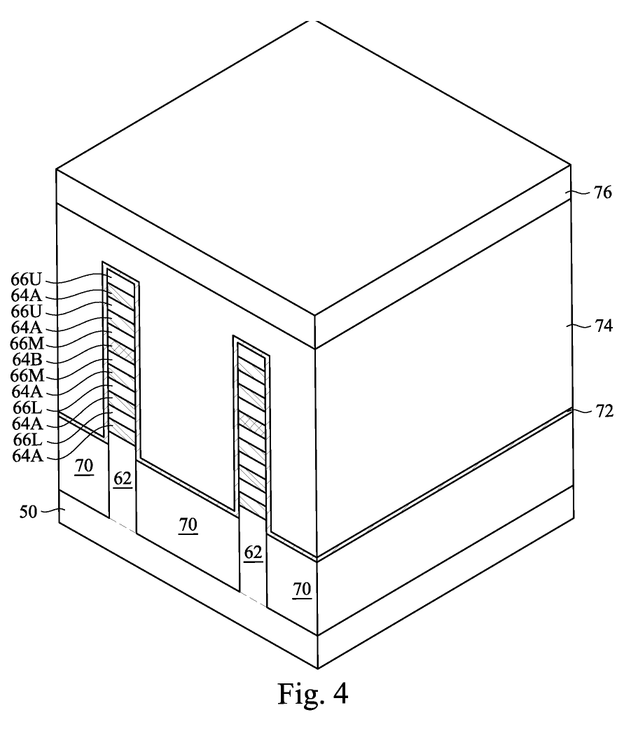

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

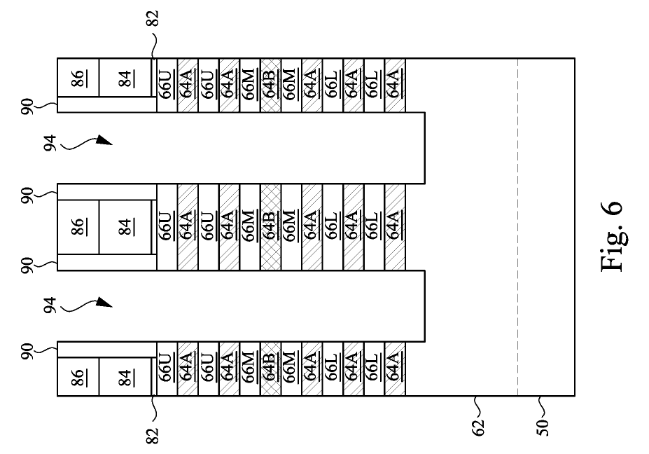

In FIG. 6, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the fins 62 and/or the nanostructures 64, 66.

It is noted that the previous disclosure generally describes a process of forming spacers. Other processes and sequences may be used. For example, fewer or additional spacers may be utilized, different sequence of steps may be utilized, additional spacers may be formed and removed, and/or the like.

Source/drain recesses 94 are formed in the fins 62, the nanostructures 64, 66, and the substrate 50. Epitaxial source/drain regions will be subsequently formed in the source/drain recesses 94. The source/drain recesses 94 may extend through the nanostructures 64, 66 and into the substrate 50. The fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the fins 62, the nanostructures 64, 66, and the substrate 50 using anisotropic etching processes, such as RIE, NBE, or the like. The gate spacers 90 and the dummy gates 84 mask portions of the fins 62, the nanostructures 64, 66, and the substrate 50 during the etching processes used to form the source/drain recesses 94. A single etch process or multiple etch processes may be used to etch each layer of the nanostructures 64, 66 and/or the fins 62. Timed etch processes may be used to stop the etching of the source/drain recesses 94 after the source/drain recesses 94 reach a desired depth.

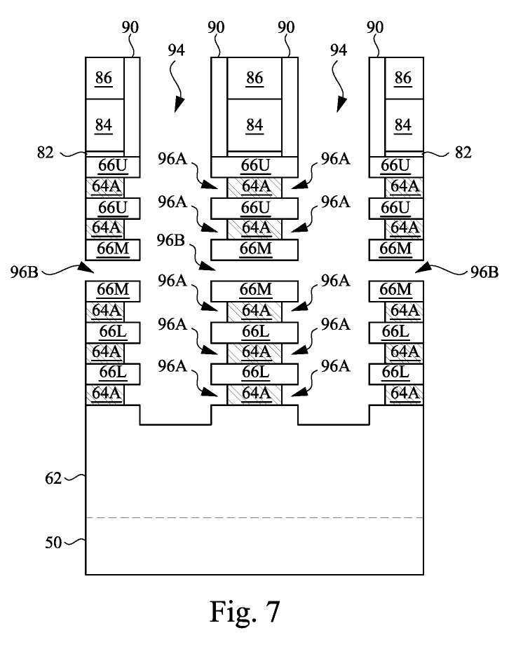

In FIG. 7, the sidewalls of the first dummy nanostructures 64A exposed by the source/drain recesses 94 are recessed to form sidewall recesses 96A. Additionally, the second dummy nanostructures 64B are removed to form openings 96B between the lower semiconductor nanostructures 66L (collectively) and the upper semiconductor nanostructures 66U (collectively). The sidewall recesses 96A will subsequently be filled with spacers. The openings 96B will subsequently be filled with isolation structures.

The sidewall recesses 96A may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex.

The openings 96B may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings 96B.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the material of the first dummy nanostructures 64A. Thus, the etch rate of the first dummy nanostructures 64A is less than the etch rate of the second dummy nanostructures 64B and is greater than the etch rate of the semiconductor nanostructures 66. In some embodiments where the second dummy nanostructures 64B are formed of germanium or silicon germanium with a high germanium atomic percentage, the first dummy nanostructures 64A are formed of silicon germanium with a low germanium atomic percentage, and the semiconductor nanostructures 66 are formed of silicon free from germanium, the etch process may comprise a dry etch process using chlorine gas, with or without a plasma.

The middle semiconductor nanostructures 66M are exposed by the openings 96B. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U. In some embodiments, the middle semiconductor nanostructures 66M are from 0% to 20% thinner than the lower semiconductor nanostructures 66L and the upper semiconductor nanostructures 66U after the etching process.

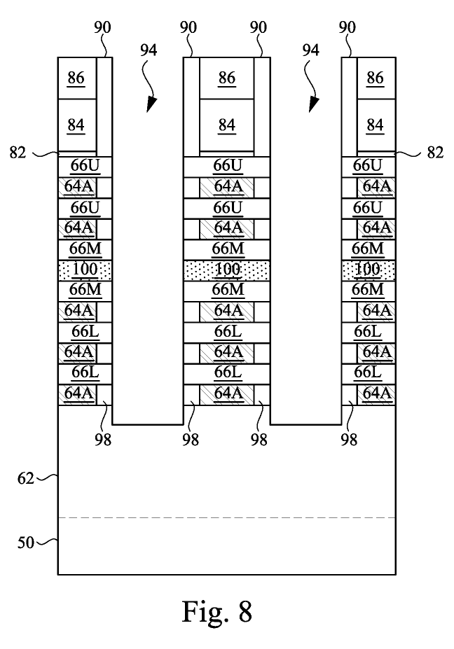

In FIG. 8, inner spacers 98 are formed in the sidewall recesses 96A and on the sidewalls of the remaining portions of the first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, isolation structures 100 are formed in the openings 96B and between the middle semiconductor nanostructures 66M. The isolation structures 100 and the middle semiconductor nanostructures 66M will define the boundaries of the lower nanostructure-FETs and the upper nanostructure-FETs.

The inner spacers 98 and the isolation structures 100 may be formed by conformally forming an insulating material in the source/drain recesses 94, the sidewall recesses 96A, and the openings 96B, and then subsequently etching the insulating material. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses 96A (thus forming the inner spacers 98) and has portions remaining in the openings 96B (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses 96A and the openings 96B, respectively. Moreover, although the sidewalls of the inner spacers 98 and the isolation structures 100 are illustrated as being straight, those sidewalls may be concave or convex.

The isolation structures 100 have similar dimensions as the second dummy nanostructures 64B they replaced. Accordingly, the isolation structures 100 may have a large thickness, such as a greater thickness than the semiconductor nanostructures 66 and the first dummy nanostructures 64A, or the isolation structures 100 may have a small thickness, such as a lesser thickness than the semiconductor nanostructures 66 and the first dummy nanostructures 64A. In some embodiments, the isolation structures 100 are from 60% to 90% thinner than the semiconductor nanostructures 66 and the isolation structures 100 are from 40% to 90% thinner than the first dummy nanostructures 64A.

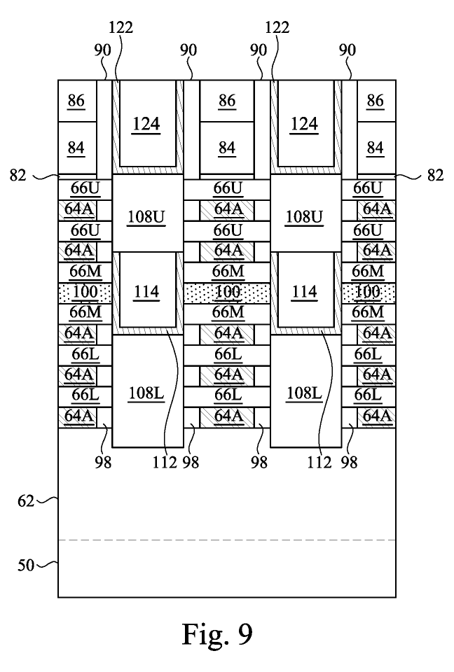

In FIG. 9, lower epitaxial source/drain regions 108L and upper epitaxial source/drain regions 108U are formed in the source/drain recesses 94. A first contact etch stop layer (CESL) 112 and/or a first inter-layer dielectric (ILD) 114 may also be formed in the source/drain recesses 94. The first ILD 114 is between the upper epitaxial source/drain regions 108U and the lower epitaxial source/drain regions 108L. The lower epitaxial source/drain regions 108L are for lower nanostructure-FETs of the CFETs, and the upper epitaxial source/drain regions 108U are for upper nanostructure-FETs of the CFETs. The first ILD 114 thus acts as isolation regions to prevent shorting of the lower and upper nanostructure-FETs. Additionally, a second CESL 122 and/or a second ILD 124 may be formed on the upper epitaxial source/drain regions 108U.

The lower epitaxial source/drain regions 108L are in contact with the lower semiconductor nanostructures 66L and are not in contact with the upper semiconductor nanostructures 66U. In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 are used to separate the lower epitaxial source/drain regions 108L from the first dummy nanostructures 64A, which will be replaced with gate structures in subsequent processes.

The lower epitaxial source/drain regions 108L are epitaxially grown in the lower portions of the source/drain recesses 94. For example, the lower epitaxial source/drain regions 108L may be grown laterally from exposed sidewalls of the lower semiconductor nanostructures 66L, as well as bottom surfaces of the fins 62/substrate 50 in the source/drain recesses 94. During the epitaxy of the lower epitaxial source/drain regions 108L, the middle semiconductor nanostructures 66M and/or the upper semiconductor nanostructures 66U may be masked to prevent undesired epitaxial growth on the middle semiconductor nanostructures 66M and/or the upper semiconductor nanostructures 66U. After the lower epitaxial source/drain regions 108L are grown, the masks on the middle semiconductor nanostructures 66M and/or the upper semiconductor nanostructures 66U may then be removed. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

The lower epitaxial source/drain regions 108L may be implanted with dopants to form source/drain regions, followed by an anneal. The source/drain regions may have an impurity concentration in the range of 10¹⁹ atoms/cm³ and 10²¹ atoms/cm³. For example, an n-type impurity implant or a p-type impurity implant may be performed. The n-type impurities may be phosphorus, arsenic, antimony, or the like. The p-type impurities may be boron, boron fluoride, indium, or the like. In some embodiments, the lower epitaxial source/drain regions 108L are in situ doped during growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed. In other embodiments, these facets cause adjacent lower epitaxial source/drain regions 108L of a same nanostructure-FET to merge.

The first ILD 114 is formed over the lower epitaxial source/drain regions 108L. The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 112 may be formed between the first ILD 114 and the lower epitaxial source/drain regions 108L. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, the sidewalls of the upper semiconductor nanostructures 66U are exposed.

The upper epitaxial source/drain regions 108U are in contact with the upper semiconductor nanostructures 66U and are not in contact with the lower semiconductor nanostructures 66L. In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 are used to separate the upper epitaxial source/drain regions 108U from the first dummy nanostructures 64A, which will be replaced with gate structures in subsequent processes.

The upper epitaxial source/drain regions 108U are epitaxially grown in the upper portions of the source/drain recesses 94. For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions. For example, if the upper semiconductor nanostructures 66U are silicon, the upper epitaxial source/drain regions 108U may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U may have surfaces raised from respective upper surfaces of the upper semiconductor nanostructures 66U and may have facets.

The upper epitaxial source/drain regions 108U may be implanted with dopants to form source/drain regions, followed by an anneal. The source/drain regions may have an impurity concentration in the range of 10¹⁹ atoms/cm³ and 10²¹ atoms/cm³. For example, an n-type impurity implant or a p-type impurity implant may be performed. The n-type impurities may be phosphorus, arsenic, antimony, or the like. The p-type impurities may be boron, boron fluoride, indium, or the like. In some embodiments, the upper epitaxial source/drain regions 108U are in situ doped during growth.

As a result of the epitaxy processes used to form the upper epitaxial source/drain regions 108U, upper surfaces of the upper epitaxial source/drain regions 108U have facets which expand laterally outward beyond sidewalls of the nanostructures 64, 66. In some embodiments, adjacent upper epitaxial source/drain regions 108U remain separated after the epitaxy process is completed. In other embodiments, these facets cause adjacent upper epitaxial source/drain regions 108U of a same nanostructure-FET to merge.

The second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 122 may be formed between the second ILD 124 and the upper epitaxial source/drain regions 108U. The second CESL 122 may be formed of a dielectric material having a high etching selectivity to the dielectric material of the second ILD 124, such as, silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

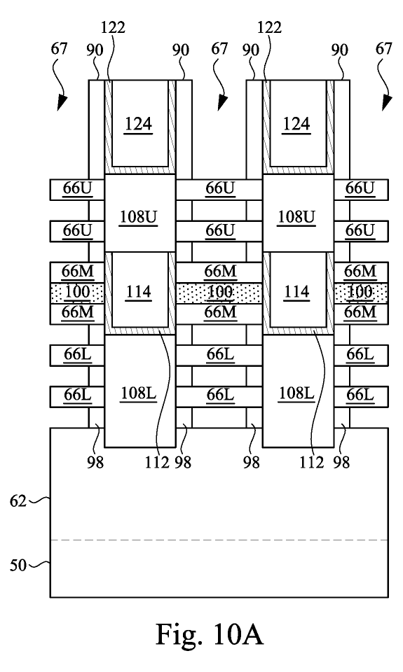

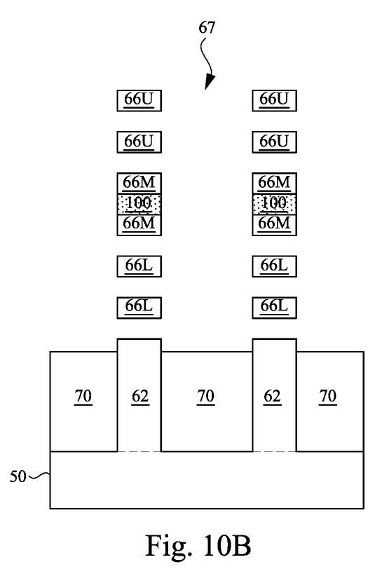

In FIGS. 10A and 10B, the dummy gates 84 are removed in one or more etching steps, so that recesses 67 are formed between the gate spacers 90. Portions of the dummy dielectrics 82 in the recesses 67 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess 67 between the gate spacers 90 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to extend the recesses 67 and form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings between the semiconductor nanostructures 66.

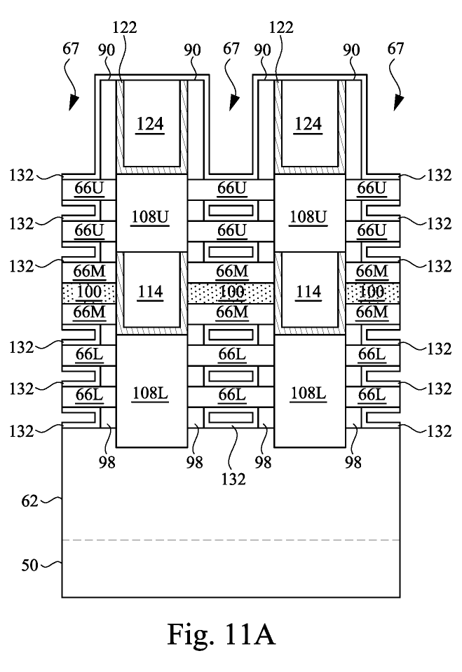

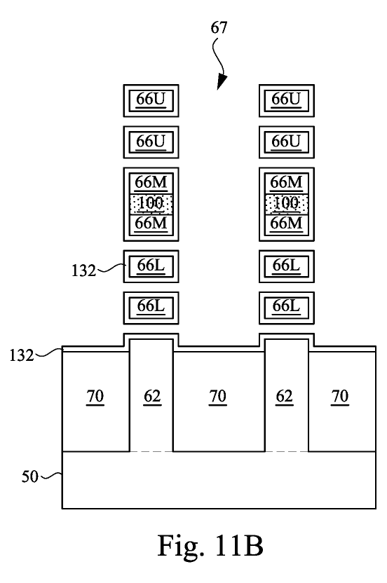

In FIGS. 11A and 11B, gate dielectrics 132 may be deposited in the recesses 67, such as between the gate spacers 90 and the openings between the semiconductor nanostructures 66. The gate dielectrics 132 may also be deposited on the top surfaces of the second ILD 124 and the gate spacers 90. The gate dielectrics 132 may include one or more gate dielectric layer(s) disposed around the lower semiconductor nanostructures 66L, the upper semiconductor nanostructures 66U, and the isolation structures 100. Specifically, the gate dielectrics 132 are disposed on the top surfaces of the fins 62; on the top surfaces, the sidewalls, and the bottom surfaces of the semiconductor nanostructures 66; and on the sidewalls of the gate spacers 90. The gate dielectrics 132 wrap around all (e.g., four) sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. In an embodiment, the gate dielectrics 132 may comprise a dielectric material having a dielectric constant that is greater than a dielectric constant of a dielectric material of the gate spacers 90. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

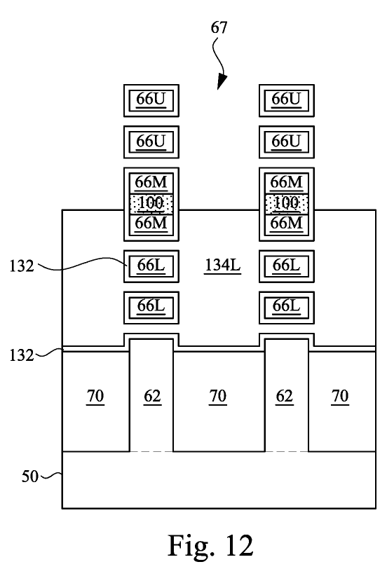

FIG. 12 illustrates the formation of lower gate electrodes 134L. The lower gate electrodes 134L may include one or more lower gate electrode layer(s) disposed over the gate dielectrics 132 and around the lower semiconductor nanostructures 66L. The lower gate electrodes 134L are disposed in the lower portions of the recesses 67 between the gate spacers 90 and in the openings between the lower semiconductor nanostructures 66L, and between the bottommost lower semiconductor nanostructures 66L and the fins 62. In an embodiment, top surfaces of the lower gate electrodes 134L are below top surfaces of the isolation structures 100. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs. In some embodiments, the lower gate electrodes 134L include a p-type work function tuning layer, which may be formed of a p-type work function tuning metal such as titanium nitride, tantalum nitride, combinations thereof, or the like. In some embodiments, the lower gate electrodes 134L include an n-type work function tuning layer, which may be formed of an n-type work function tuning metal such as titanium aluminum, titanium aluminum carbide, tantalum aluminum, tantalum carbide, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

As an example to form the lower gate electrodes 134L, the one or more lower gate electrode layer(s) are formed over the gate dielectrics 132 and in the remaining portions of the recesses 67 between the gate spacers 90 and the openings between the semiconductor nanostructures 66. The lower gate electrode layer(s) may be formed, for example, using a suitable deposition process, such as CVD, ALD, or the like. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses 67 between the gate spacers 90, such that the lower gate electrode layer(s) remain in the openings between the lower semiconductor nanostructures 66L.

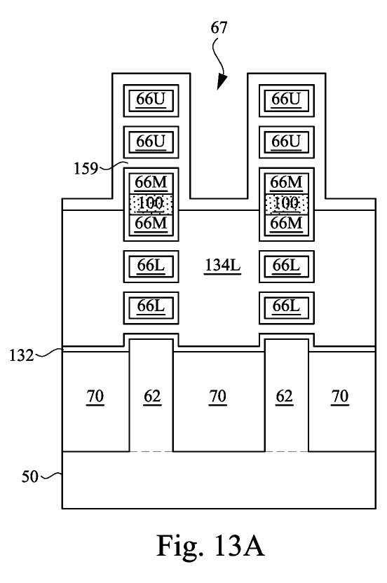

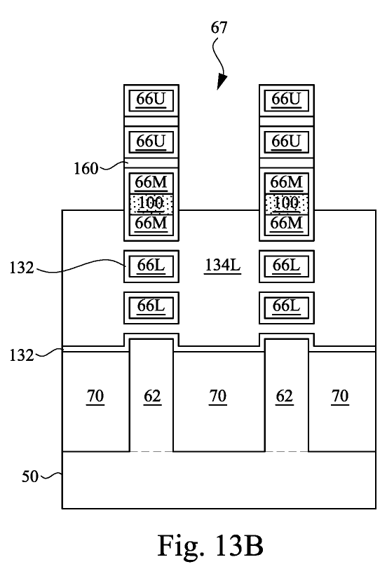

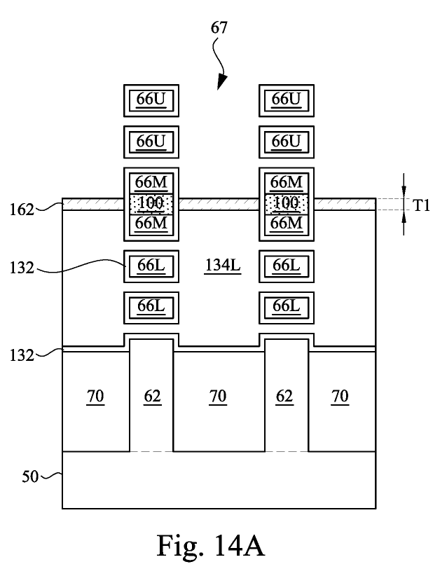

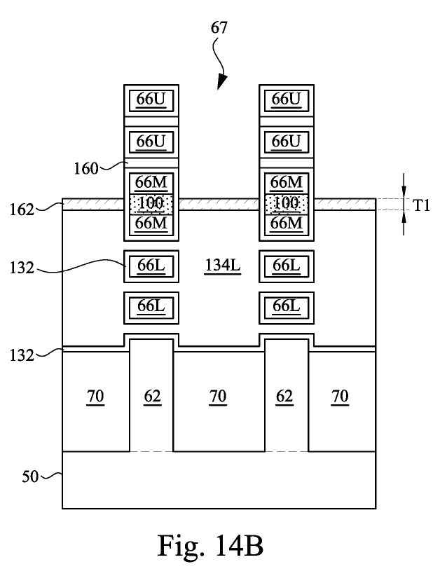

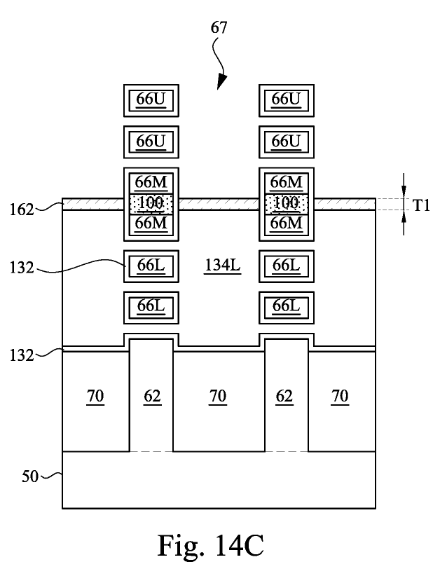

FIGS. 13A and 13B illustrates optional steps that are used to form masking structures 160 to fill the openings between the upper semiconductor nanostructures 66U, and to fill the openings between the middle semiconductor nanostructures 66M above the isolation structures 100 and adjacent upper semiconductor nanostructures 66U. The masking structures 160 may be used as deposition masks during the formation of the dummy layer 162 (shown subsequently in FIG. 14B). In some embodiments, the steps shown in FIGS. 13A and 13B may be omitted.

As an example of how to form the masking structures 160, as shown in FIG. 13A, a dielectric layer 159 may be deposited in the recesses 67 and over the structure shown previously in FIG. 12, such as over the gate dielectrics 132 and the lower gate electrodes 134L, and around the upper semiconductor nanostructures 66U to fill the openings between the upper semiconductor nanostructures 66U. In addition, the dielectric layer 159 fills the openings between the middle semiconductor nanostructures 66M above the isolation structures 100 and adjacent upper semiconductor nanostructures 66U. Further, the dielectric layer 159 may be formed over top surfaces and on sidewalls of the gate spacers 90, and over top surfaces of the second ILD 124.

The dielectric layer 159 may comprise a material such as aluminum oxide, lanthanum oxide, tantalum oxide, or the like, that is conformally deposited using a suitable process such as ALD, CVD, or the like. As shown in FIG. 13B, after the formation of the dielectric layer 159, an etching process (e.g., that may comprise reactive ion etching (RIE), neutral beam etching (NBE), chemical etching, radical etching, or the like) may be performed to remove portions of the dielectric layer 159 that are disposed over the lower gate electrodes 134L, on sidewalls of the upper semiconductor nanostructures 66U, and over topmost ones of the upper semiconductor nanostructures 66U. In an embodiment, the etching process may also remove portions of the dielectric layer 159 that are disposed on the top surfaces and sidewalls of the gate spacers 90, and on the top surfaces of the second ILD 124. In an embodiment, an additional trimming process (e.g., using a suitable wet etch process) may also be performed to remove end portions of the dielectric layer 159 between the upper semiconductor nanostructures 66U. In an embodiment, after the etching process and the trimming process are performed, remaining portions of the dielectric layer 159 form the masking structures 160 that are disposed between the upper semiconductor nanostructures 66U, and between the middle semiconductor nanostructures 66M above the isolation structures 100 and adjacent upper semiconductor nanostructures 66U. Although outer sidewalls of the masking structures 160 are illustrated as being flush with sidewalls of the gate dielectrics 132, the outer sidewalls of the masking structures 160 may extend beyond or be recessed from sidewalls of the gate dielectrics 132.

In FIG. 14A, a dummy layer 162 is selectively deposited on exposed surfaces (e.g., top surfaces) of the lower gate electrodes 134L in the recesses 67 of the structure shown previously in FIG. 12. In the embodiment shown in FIG. 14A, the optional masking structures 160 that were described previously in FIGS. 13A and 13B are not present. The dummy layer 162 may also be referred to subsequently as a polymer layer. In an embodiment, the dummy layer 162 may comprise an anionic polymer, such as, for example, polyacrylic acid (PAA), polyvinyl alcohol (PVA), or the like. The dummy layer 162 may be formed using a spin-on coating process, or the like, that is used to deposit a spin-on coating solution having an anionic polymer concentration that is in a range from 10 percent to 40 percent by weight. The spin-on coating solution may also comprise a solvent such as water, isopropyl alcohol (IPA), methanol, ethanol, glycerol, or the like. In an embodiment, a thickness T1 of the dummy layer 162 may be in a range from 5 nm to 50 nm. The thickness T1 of the dummy layer 162 may be controlled by adjusting the anionic polymer concentration in the spin-on coating solution and/or by adjusting the number of spin-on coating cycles of the spin-on coating process that are performed. For example, increasing the concentration of the anionic polymer in the spin-on coating solution or increasing the number of spin-on coating cycles may result in a larger thickness T1 of the dummy layer 162, while decreasing the concentration of the anionic polymer in the spin-on coating solution or reducing the number of spin-on coating cycles may result in a smaller thickness T1 of the dummy layer 162.

An anionic polymer is a compound that comprises a long chain of carbon atoms that have negatively charged functional groups attached along the chain. During the deposition of the dummy layer 162, surface charge interactions occur between the negatively charged functional groups of the anionic polymer and the underlying materials. These charged functional groups preferentially interact with the positively charged surface sites present on surfaces (e.g., the top surfaces) of the lower gate electrodes 134L (e.g., comprising titanium nitride, or the like) while showing minimal interaction with the neutral or negatively charged surface sites on surfaces of the gate dielectrics 132. As a result, the dummy layer 162 is selectively formed on the top surfaces of the lower gate electrodes 134L, and the formation of the dummy layer 162 on the surfaces of the gate dielectrics 132 is inhibited.

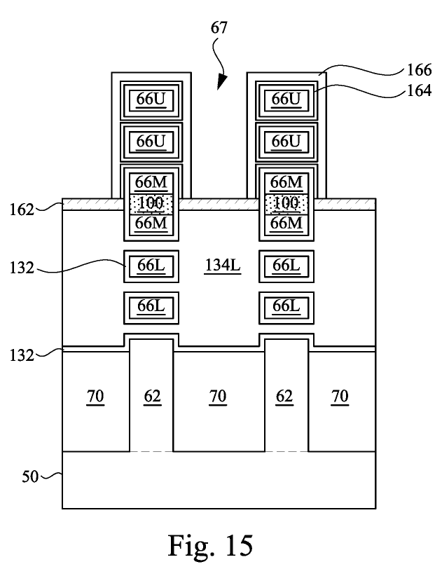

Advantages can be achieved by selectively forming the dummy layer 162 on exposed surfaces (e.g., the top surfaces) of the lower gate electrodes 134L in the recesses 67, wherein the dummy layer 162 comprises an anionic polymer, such as, for example, polyacrylic acid (PAA), polyvinyl alcohol (PVA), or the like. The dummy layer 162 may be formed using a spin-on coating process, or the like, that is used to deposit a spin-on coating solution having an anionic polymer concentration that is in a range from 10 percent to 40 percent by weight. These advantages include the forming of the dummy layer 162 using the spin-on coating process, wherein the anionic polymer concentration in the spin-on coating solution being in the range from 10 percent to 40 percent by weight resulting in the dummy layer 162 being formed only on surfaces of the lower gate electrodes 134L, and not on surfaces of the gate dielectrics 132 around the semiconductor nanostructures 66. As a result, a conductive layer 164 and a conductive layer 166 may be subsequently formed over the gate dielectrics 132, and around the semiconductor nanostructures 66 in the recesses 67 (described subsequently in FIG. 15) without requiring additional masking or etching steps to remove any portions of the dummy layer 162 around the semiconductor nanostructures 66. Additionally, forming the dummy layer 162 over the lower gate electrodes 134L using the spin-on coating process, or the like, that is used to deposit a spin-on coating solution having an anionic polymer concentration that is in the range from 10 percent to 40 percent by weight allows for the subsequent formation of the conductive layer 164 (described in FIG. 15) and the conductive layer 166 (described in FIG. 15) over the gate dielectrics 132, and around the semiconductor nanostructures 66 in the recesses 67 to be selective. For example, the presence of the polymer compounds in the dummy layer 162 creates surfaces that lack the reactive sites needed for the formation of the conductive layer 164 and the conductive layer 166, and as a result, the formation of the conductive layer 164 and the conductive layer 166 on surfaces of the dummy layer 162 is inhibited. This leads to improved control over the placement of the conductive layer 164 and the conductive layer 166, and reduces the need for subsequent patterning or removal steps, thereby simplifying the overall fabrication process and improving manufacturing yields.

In some embodiments, the dummy layer 162 may also include a nonionic polymer. For example, in addition to the anionic polymer, the spin-on coating solution that is used to form the dummy layer 162 may also comprise a nonionic polymer, such as polyacrylamide, polyethylene glycol (also referred to as polyethylene oxide), polystyrene sulfonate, polyvinyl pyrrolidone, or the like. A nonionic polymer is a compound that comprises macromolecules that do not contain ionic bonds, ions, or functional groups that would ionize in an aqueous solution. In an embodiment, when the nonionic polymer is added to the anionic polymer (e.g., in the spin-coating solution), an insoluble molecular structure (e.g., also referred to as a complex) is formed through hydrogen bonding or other non-covalent interactions. In an embodiment, the spin-on coating solution may have a first percentage concentration of the solvent by weight, a second percentage concentration of the anionic polymer by weight, and a third percentage concentration of the nonionic polymer by weight, wherein the first percentage concentration is greater than the second percentage concentration, and the second percentage concentration is greater than the third percentage concentration.

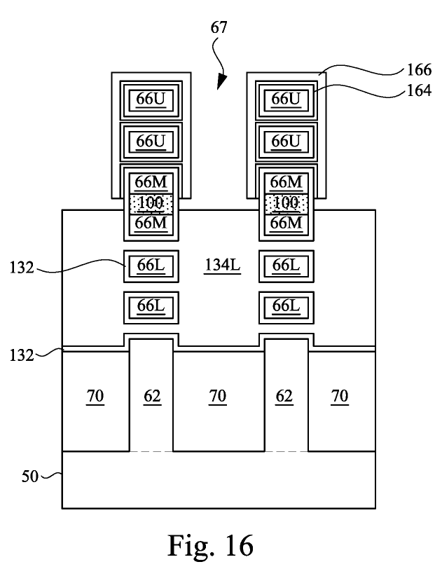

In an embodiment, when the nonionic polymer is added to the anionic polymer (e.g., in the spin-on coating solution), the anionic polymer and nonionic polymer can interact through hydrogen bonding or other non-covalent interactions to form a molecular structure (also referred to as complex) that has a different solubility property than the individual polymers. After the dummy layer 162 is formed using the spin-on coating process, the solubility of the molecular structure in the dummy layer 162 may be controlled by adjusting a pH level of water or a water-based solution that the dummy layer 162 is exposed to and that can be subsequently used to remove the dummy layer 162 (e.g., as shown in FIG. 16).

Advantages can be achieved by forming the dummy layer 162, wherein the dummy layer 162 comprises a nonionic polymer and an anionic polymer. A spin-on coating process is performed to form the dummy layer 162 using a spin-on coating solution that comprises the anionic polymer and the nonionic polymer, wherein the nonionic polymer comprises polyacrylamide, polyethylene glycol (also referred to as polyethylene oxide), polystyrene sulfonate, polyvinyl pyrrolidone, or the like. These advantages include the anionic polymer and nonionic polymer interacting to form a molecular structure (also referred to as complex) that has a different solubility property than the individual polymers (e.g., the anionic polymer or the nonionic polymer). This allows for the control of a solubility of the dummy layer 162 in water or a water-based solution by adjusting a pH level of that water or water-based solution. For example, as described subsequently in FIG. 16, when the pH level of the water or water-based solution is equal to or higher than 7, the solubility of the dummy layer 162 (e.g., that comprises the anionic polymer and the nonionic polymer) in that water or water-based solution increases, which allows for the selective removal of the dummy layer 162 without the need to use other etching processes (e.g., dry etching processes, or the like) that could potentially damage the conductive layer 164 (described subsequently in FIG. 15) and the conductive layer 166 (described subsequently in FIG. 15) or other underlying device structures. As a result, device reliability can be improved and improved manufacturing yields can be achieved.

FIGS. 14B and 14C illustrate an alternative embodiment in which the optional masking structures 160 that were described previously in FIGS. 13A and 13B are present. In FIG. 14B, the dummy layer 162 is selectively deposited on exposed surfaces (e.g., top surfaces) of the lower gate electrodes 134L in the recesses 67 of the structure shown previously in FIG. 13B using similar processes and materials as were described previously in FIG. 14A. During this selective deposition process, the masking structures 160 may function as deposition masks. FIG. 14C illustrates that after the formation of the dummy layer 162, the masking structures 160 may be removed using an etching process. In an embodiment, the etching process may be an isotropic etching process, such as wet etching, or the like, that uses ammonium hydroxide (NH₄OH), hydrogen peroxide (H₂O₂), or the like, as an etchant.

In FIG. 15, the conductive layer 164 and the conductive layer 166 may be selectively deposited over the gate dielectrics 132, and around the semiconductor nanostructures 66 in the recesses 67 of the structure shown previously in FIG. 14A or 14C, such that the conductive layer 164 and the conductive layer 166 are not formed on surfaces (e.g., top surfaces) of the dummy layer 162. In an embodiment, the conductive layer 164 (which may also be referred to as a metal-containing layer) and the conductive layer 166 (which may also be referred to as a metal-containing layer) are deposited sequentially. The conductive layer 164 may comprise titanium aluminum, or the like, that is conformally deposited using a suitable deposition process such as CVD, ALD, or the like. In an embodiment, the conductive layer 164 may be deposited over the gate dielectrics 132 and around the upper semiconductor nanostructures 66U. The conductive layer 164 may also be formed over top surfaces of the middle semiconductor nanostructures 66M and on sidewalls of the middle semiconductor nanostructures 66M. In some embodiments, the conductive layer 164 may also be formed on sidewalls of the isolation structures 100. During the deposition process to form the conductive layer 164, the formation of the conductive layer 164 on surfaces of the dummy layer 162 is inhibited due to the presence of the polymer compounds in the dummy layer 162, which create surfaces that lack the reactive sites needed for the formation of the conductive layer 164.

The conductive layer 166 may comprise titanium nitride, tantalum nitride, tantalum oxide, titanium silicon nitride, titanium aluminum carbide, or the like, that is conformally deposited using a suitable deposition process such as CVD, ALD, or the like. In an embodiment, the conductive layer 166 may be deposited over the conductive layer 164, the gate dielectrics 132 and around the upper semiconductor nanostructures 66U to fill the openings between the upper semiconductor nanostructures 66U. The conductive layer 166 may also be formed over top surfaces of the middle semiconductor nanostructures 66M and on sidewalls of the middle semiconductor nanostructures 66M. In addition, the conductive layer 166 may also be formed on sidewalls of the isolation structures 100. During the deposition process to form the conductive layer 166, the formation of the conductive layer 166 on surfaces of the dummy layer 162 is inhibited due to the presence of the polymer compounds in the dummy layer 162, which create surfaces that lack the reactive sites needed for the formation of the conductive layer 166.

In FIG. 16, the dummy layer 162 may be removed by exposing surfaces of the dummy layer 162 to water or a water-based solution having a controlled pH level. For example, in an embodiment, during the formation of the dummy layer 162 (described previously in FIG. 14A), the anionic polymer and nonionic polymer can interact through hydrogen bonding or other non-covalent interactions to form the dummy layer 162 having a molecular structure (also referred to as complex) that has a different solubility property than the individual polymers (e.g., the anionic polymer or the nonionic polymer). In an embodiment where the dummy layer 162 comprises both an anionic polymer and a nonionic polymer, exposing the dummy layer 162 to water or a water-based solution having a pH level that is equal to or higher than 7 may increase the solubility of the dummy layer 162 in that water or water-based solution. As a result, exposure of the dummy layer 162 to that water or water-based solution will facilitate the removal of the dummy layer 162.

As an example, the dummy layer 162 may comprise an anionic polymer and a nonionic polymer that interact to form a molecular structure (also referred to as complex), wherein the anionic polymer is polyacrylic acid (PAA), and the nonionic polymer is polyethylene glycol. Polyacrylic acid (PAA) may comprise a polymer chain with repeating units, wherein each repeating unit of the polymer chain contains a carboxyl group (-COOH), and wherein a carboxyl group (-COOH) comprises a carbon atom double-bonded to an oxygen atom and single-bonded to a hydroxyl group (-OH). When polyethylene glycol is present, the polyacrylic acid interacts with the polyethylene glycol to form a molecular structure that is stable at a pH level that is lower than 7. However, when the pH level of the water or water-based solution that is used to remove the dummy layer 162 is equal to or higher than 7 (e.g., made more basic), the hydrogen atom (also referred to as a proton) from the hydroxyl group (-OH) of the carboxyl group is removed (also referred to as deprotonation), thereby converting the carboxyl group (-COOH) to a negatively charged carboxylate ion (-COO-). The conversion to carboxylate ions increases the negative charge density along the polymer chain, which makes the polyacrylic acid more hydrophilic and increases its solubility. The increased negative charge density of the polymer chain also disrupts the hydrogen bonding between the polyacrylic acid (PAA) and polyethylene glycol, which facilitates the breakdown of the molecular structure and allows for the removal of the dummy layer 162.

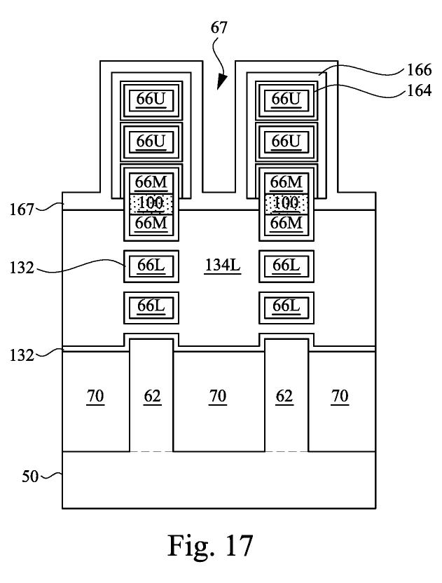

In FIG. 17, a dielectric layer 167 is deposited in the recesses 67 and over the structures illustrated in FIG. 16 using a conformal deposition process, such as CVD, ALD, or the like. The dielectric layer 167 may comprise silicon oxide, silicon nitride, silicon oxynitride, silicon oxycarbonitride, combinations thereof, or the like. The dielectric layer 167 may be formed over the lower gate electrodes 134L, the upper semiconductor nanostructures 66U, the conductive layer 164, the conductive layer 166, the gate dielectrics 132 and the isolation structures 100. For example, the dielectric layer 167 may be disposed on top surfaces of the lower gate electrodes 134L, on top surfaces, sidewalls, and bottom surfaces of the conductive layer 166, on bottom surfaces of the conductive layer 164, and on sidewalls of the gate dielectrics 132. In an embodiment, the dielectric layer 167 fills spaces (e.g., previously occupied by the dummy layer 162 that was removed as described in FIG. 16) between bottom surfaces of the conductive layer 164 and the conductive layer 166, and top surfaces of the lower gate electrodes 134L.

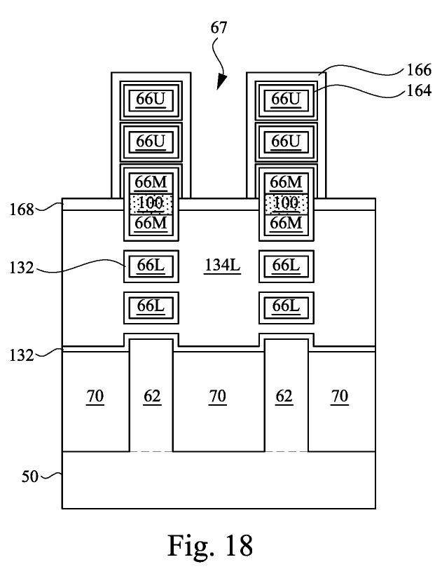

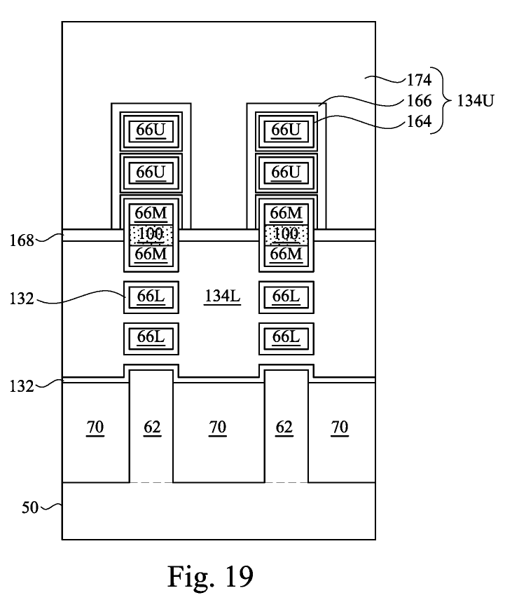

In FIG. 18, after the formation of the dielectric layer 167, an etching process (e.g., that may comprise reactive ion etching (RIE), neutral beam etching (NBE), or the like) may be performed to remove portions of the dielectric layer 167 that are disposed on top surfaces and sidewalls of the conductive layer 166. In addition, during the performing of the etching process, a thickness of portions of the dielectric layer 167 that are disposed over the lower gate electrodes 134L may be reduced. In an embodiment, after the etching process is performed, remaining portions of the dielectric layer 167 form an isolation layer 168. The isolation layer 168 acts as an isolation feature that is disposed between the lower gate electrodes 134L and the subsequently formed upper gate electrodes 134U (described subsequently in FIG. 19). The isolation layer 168 and the isolation structures 100 together physically and electrically isolate the upper gate electrodes 134U from the lower gate electrodes 134L. In addition, an upper nanostructure-FET may be isolated from a lower nanostructure-FET by an isolation structure 100.

In FIG. 19, one or more upper gate electrode layer(s) 174 are formed in the recesses 67 over the isolation layer 168, the lower gate electrodes 134L, the conductive layer 166, the conductive layer 166, the gate dielectrics 132 and the upper semiconductor nanostructures 66U. The one or more upper gate electrode layer(s) 174 may be in contact with top surfaces and sidewalls of the conductive layer 166, and top surfaces of the isolation layer 168. In an embodiment, bottom surfaces of the one or more upper gate electrode layer(s) 174 may be higher than bottom surfaces of the isolation structures 100, and the bottom surfaces of the one or more upper gate electrode layer(s) 174 may be below top surfaces of the isolation structures 100. In an embodiment, bottom surfaces of the conductive layer 166 and the conductive layer 164 may be higher than bottom surfaces of the isolation structures 100, and the bottom surfaces of the conductive layer 166 and the conductive layer 164 may be below top surfaces of the isolation structures 100. In an embodiment, sidewalls of the conductive layer 166 and the conductive layer 164 are disposed adjacent to a sidewall of the isolation structures 100. In an embodiment, the conductive layer 166, the conductive layer 164, and the one or more upper gate electrode layer(s) 174 collectively form the upper gate electrodes 134U that are disposed over the gate dielectrics 132 and around the upper semiconductor nanostructures 66U. The upper gate electrodes 134U are disposed in the upper portions of the recesses 67 between the gate spacers 90 and in the openings between the upper semiconductor nanostructures 66U. The one or more upper gate electrode layer(s) 174 may be formed of a metal-containing material such as tungsten, titanium, titanium nitride, tantalum, tantalum nitride, tantalum carbide, aluminum, ruthenium, cobalt, combinations thereof, multi-layers thereof, or the like. For example, in an embodiment, the upper semiconductor nanostructures 66U may form channel regions for subsequently formed upper nanostructure-FETs. In an embodiment in which the subsequently formed upper nanostructure-FETs are n-type devices, the one or more gate electrode layer(s) 174 may be formed of a metal-containing material such as titanium nitride, or the like. In an embodiment, the upper gate electrodes 134U may include any number of work function tuning layers, any number of barrier layers, any number of glue layers, and a fill material.

In an embodiment, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L. In an embodiment, the isolation layer 168 and the isolation structures 100 together electrically isolate the upper gate electrodes 134U from the lower gate electrodes 134L. In addition, an upper nanostructure-FET may be isolated from a lower nanostructure-FET by an isolation structure 100.

As an example, to form the one or more upper gate electrode layer(s) 174, the one or more upper gate electrode layer(s) 174 are formed in the recesses 67 over the isolation layer 168, the lower gate electrodes 134L, the conductive layer 166, the conductive layer 166, the gate dielectrics 132 and the upper semiconductor nanostructures 66U. For example, a suitable conformal deposition process, such as CVD, ALD, or the like, is used to form the one or more upper gate electrode layer(s) 174 in the upper portions of the recesses 67 and over the lower gate electrodes 134L and the isolation layer 168. The conductive layer 166, the conductive layer 164, and the one or more upper gate electrode layer(s) 174 of the upper gate electrodes 134U may not be separately shown in subsequent figures, and instead may be shown collectively as the upper gate electrodes 134U.

In FIG. 20, a removal process may be performed to remove the excess portions of the one or more upper gate electrode layer(s) 174 and/or the gate dielectrics 132, which excess portions are over the top surfaces of the gate spacers 90 and the second ILD 124. In some embodiments, a planarization process such as a chemical mechanical polish (CMP), an etch-back process, combinations thereof, or the like may be utilized. When a planarization process is utilized, the top surfaces of the gate spacers 90, the second ILD 124, the gate dielectrics 132, and the upper gate electrodes 134U are coplanar (within process variations).

The gate dielectrics 132 and gate electrodes 134 (including the lower gate electrodes 134L and the upper gate electrodes 134U) form replacement gates. Each respective pair of a gate dielectric 132 and a gate electrode 134 (including an upper gate electrode 134U and/or a lower gate electrode 134L) may be collectively referred to as a “gate structure” or a “gate stack”. Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62.

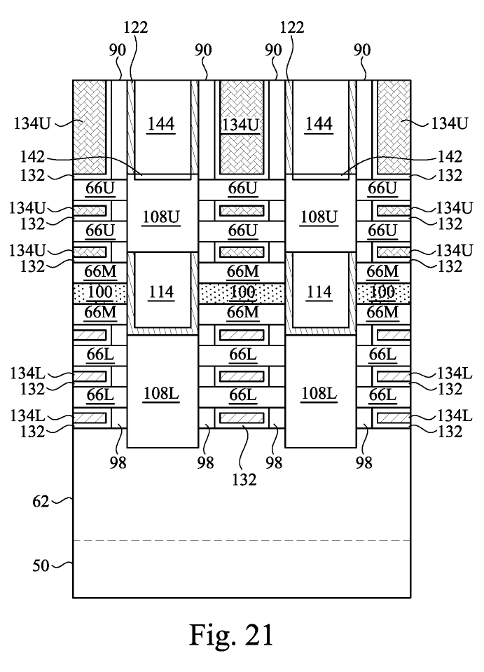

In FIG. 21, source/drain contacts 144 are formed through the second ILD 124 to electrically couple to the upper epitaxial source/drain regions 108U and/or the lower epitaxial source/drain regions 108L. As an example to form the source/drain contacts 144, openings for the source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90, the second ILD 124 (see FIG. 20), and the upper gate electrodes 134U. The remaining liner and conductive material form the source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124 (see FIG. 20), the upper gate electrodes 134U, and the source/drain contacts 144 are substantially coplanar (within process variations).

Optionally, metal-semiconductor alloy regions 142 are formed at the interfaces between the source/drain regions 108 and the source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 142. The material(s) of the source/drain contacts 144 can then be formed on the metal-semiconductor alloy regions 142.

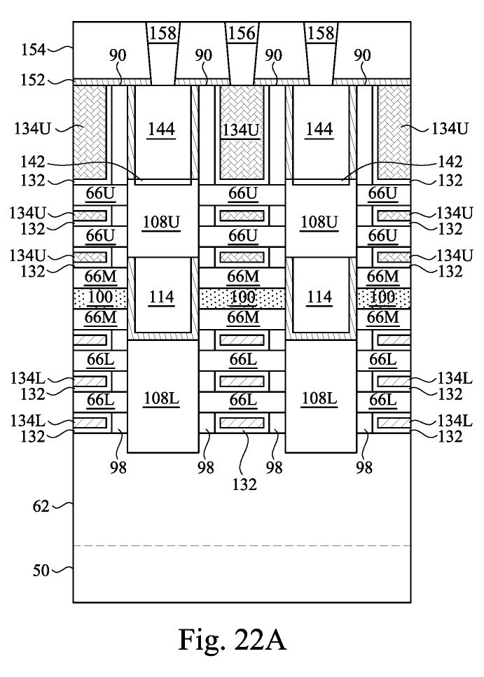

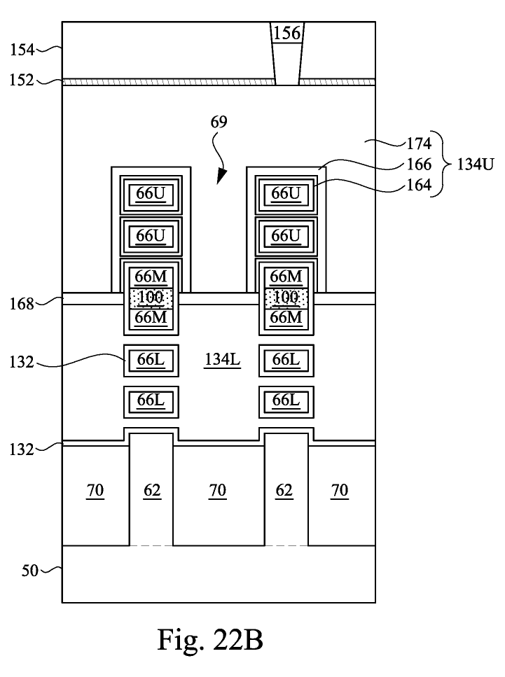

In FIGS. 22A and 22B, a third ILD 154 is deposited over the gate spacers 90, the second ILD 124, the upper gate electrodes 134U, and the source/drain contacts 144. In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the upper gate electrodes 134U, and the source/drain contacts 144. The ESL 152 may include a dielectric material having a high etching selectivity to the dielectric material of the third ILD 154, such as, silicon nitride, silicon oxide, silicon oxynitride, or the like.

Gate contacts 156 and source/drain vias 158 are formed through the third ILD 154 to electrically couple to, respectively, the upper gate electrodes 134U and the source/drain contacts 144. As an example to form the gate contacts 156 and the source/drain vias 158, openings for the gate contacts 156 and the source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the gate contacts 156 and the source/drain vias 158 in the openings. The gate contacts 156 and the source/drain vias 158 may be formed in distinct processes, or may be formed in the same process. Although shown as being formed in the same cross-section, it should be appreciated that each of the gate contacts 156 and the source/drain vias 158 may be formed in different cross-sections, which may avoid shorting of the contacts.

The active devices as illustrated are collectively referred to as a device layer. In some embodiments, contacts to the lower gate electrodes 134L and the lower epitaxial source/drain regions 108L may be made through a backside of the device layer (e.g., a side opposite to the source/drain contacts 144).

The embodiments of the present disclosure have some advantageous features. The embodiments include forming a semiconductor device that includes complementary field-effect transistors (CFETs), wherein forming the semiconductor device may include forming upper channel regions of upper nanostructure-FETs and lower channel regions of lower nanostructure-FETs, the upper channel regions and the lower channel regions being disposed over a fin. A gate dielectric layer is formed around the upper channel regions and the lower channel regions, and over the fin. Lower gate electrodes are then formed over the gate dielectric layer and around the lower channel regions. A dummy layer may be selectively deposited on exposed surfaces (e.g., top surfaces) of the lower gate electrodes such that the dummy layer is not formed on surfaces of the gate dielectric layer disposed around the upper channel regions. The dummy layer may comprise an anionic polymer such as polyacrylic acid (PAA), polyvinyl alcohol (PVA), or the like. The dummy layer may be formed using a spin-on coating process, or the like, that is used to deposit a solution having an anionic polymer concentration that is in a range from 10 percent to 40 percent by weight. In some embodiments, the dummy layer may also comprise a nonionic polymer, such as polyacrylamide, polyethylene glycol (also referred to as polyethylene oxide), polystyrene sulfonate, polyvinyl pyrrolidone, or the like. After the formation of the dummy layer, a first metal-containing material layer may be selectively formed over the gate dielectric layer and around the upper channel regions, such that the first metal-containing layer is not formed on surfaces (e.g., top surfaces) of the dummy layer. A second metal-containing material layer is then selectively formed around the first metal-containing layer and around the upper channel regions, such that the second metal-containing layer is not formed on surfaces (e.g., top surfaces) of the dummy layer. The dummy layer may then be removed using water or a water-based solution. An isolation layer (e.g., comprising a dielectric material) is then formed over the lower gate electrodes (e.g., on top surfaces of the lower gate electrodes). Upper gate electrodes are then formed over the isolation layer, and on surfaces of the second metal-containing layer and the first metal-containing layer around the upper channel regions. The isolation layer may electrically isolate the lower gate electrodes and the upper gate electrodes from each other, and the combination of the lower gate electrodes and the upper gate electrodes may be referred to subsequently as a split metal gate.

One or more embodiments disclosed herein may allow for the formation of the isolation layer that is disposed between the lower gate electrodes and the upper gate electrodes, and that electrically isolates the lower gate electrodes from the upper gate electrodes. The dummy layer (e.g., comprising an anionic polymer such as polyacrylic acid (PAA), polyvinyl alcohol (PVA), or the like) is selectively formed on the exposed surfaces (e.g., the top surfaces) of the lower gate electrodes such that the dummy layer is not formed on surfaces of the gate dielectric layer disposed around the upper channel regions. This allows for the subsequent selective formation of the first metal-containing layer and the second metal-containing layer on the surfaces of the gate dielectric layer and around the upper channel regions, such that the first metal-containing layer and the second metal-containing layer are not formed on surfaces (e.g., top surfaces) of the dummy layer. The dummy layer may then be removed using water or a water-based solution, and the isolation layer (e.g., comprising a dielectric material) is then formed over the lower gate electrodes. Upper gate electrodes may then be formed over the isolation layer, and on surfaces of the second metal-containing layer and the first metal-containing layer around the upper channel regions. As a result, the number of patterning steps (e.g., including masking and etching processes) that are used to form the isolation layer that is disposed between the upper gate electrodes and the lower gate electrodes can be reduced. In addition, the water-based removal process of the dummy layer may reduce a risk of damage to underlying device structures compared to other etching processes (e.g., dry etching processes). This may lead to improved device reliability, improved manufacturing yields, and the simplifying of the overall device fabrication process.

In accordance with an embodiment, a method includes forming a multi-layer stack over a semiconductor substrate, the multi-layer stack including alternating semiconductor nanostructures and dummy nanostructures; forming lower source/drain regions, where lower semiconductor nanostructures of the semiconductor nanostructures extend between the lower source/drain regions; forming upper source/drain regions over the lower source/drain regions, where upper semiconductor nanostructures of the semiconductor nanostructures extend between the upper source/drain regions; removing the dummy nanostructures to form first openings between the lower semiconductor nanostructures, and second openings between the upper semiconductor nanostructures; forming a gate dielectric layer around the lower semiconductor nanostructures and the upper semiconductor nanostructures; forming a lower gate electrode around the lower semiconductor nanostructures and in the first openings; selectively depositing a dummy layer over top surfaces of the lower gate electrode, the dummy layer including a first polymer; and forming an upper gate electrode around the upper semiconductor nanostructures and in the second openings, where sidewalls of the upper gate electrode are in contact with a gate spacer, where a dielectric constant of the gate dielectric layer is greater than a dielectric constant of the gate spacer, where the upper gate electrode includes a titanium-containing material. In an embodiment, the first polymer is an anionic polymer. In an embodiment, the anionic polymer includes polyacrylic acid (PAA) or polyvinyl alcohol (PVA). In an embodiment, the dummy layer also includes a second polymer, and where the second polymer is a nonionic polymer. In an embodiment, the nonionic polymer includes polyacrylamide, polyethylene glycol, polystyrene sulfonate, or polyvinyl pyrrolidone. In an embodiment, forming the upper gate electrode further includes forming a first metal-containing layer around the upper semiconductor nanostructures and in the second openings; forming a second metal-containing layer around the first metal-containing layer and in the second openings; and depositing an upper gate electrode layer over the lower gate electrode, the first metal-containing layer, and the second metal-containing layer. In an embodiment, the method further includes removing the dummy layer by exposing surfaces of the dummy layer to water or a water-based solution having a pH level that is equal to or higher than 7; and forming a dielectric layer over the top surfaces of the lower gate electrode. In an embodiment, the first metal-containing layer includes titanium aluminum, and the second metal-containing layer includes titanium nitride.

In accordance with an embodiment, a method includes forming a multi-layer stack over a semiconductor substrate, the multi-layer stack including alternating semiconductor layers and dummy layers; patterning the multi-layer stack to form a fin, where the fin includes alternating semiconductor nanostructures and dummy nanostructures, the semiconductor nanostructures defined from the semiconductor layers, and the dummy nanostructures defined from the dummy layers; forming lower source/drain regions, where lower semiconductor nanostructures of the semiconductor nanostructures extend between the lower source/drain regions; forming upper source/drain regions over the lower source/drain regions, where upper semiconductor nanostructures of the semiconductor nanostructures extend between the upper source/drain regions; removing the dummy nanostructures to form first openings between the lower semiconductor nanostructures, and second openings between the upper semiconductor nanostructures; forming a lower gate electrode around the lower semiconductor nanostructures and in the first openings; selectively depositing a polymer layer over top surfaces of the lower gate electrode, where the polymer layer includes a first polymer; selectively forming a first metal-containing layer around the upper semiconductor nanostructures and in the second openings; replacing the polymer layer with a dielectric layer; and depositing an upper gate electrode layer over the first metal-containing layer, the dielectric layer, and the lower gate electrode. In an embodiment, the first polymer is an anionic polymer that includes polyacrylic acid (PAA) or polyvinyl alcohol (PVA). In an embodiment, the polymer layer also includes a second polymer, and where the second polymer is a nonionic polymer. In an embodiment, the nonionic polymer includes polyacrylamide, polyethylene glycol, polystyrene sulfonate, or polyvinyl pyrrolidone. In an embodiment, the method further includes selectively forming a second metal-containing layer around the first metal-containing layer, around the upper semiconductor nanostructures, and in the second openings. In an embodiment, the first metal-containing layer includes titanium aluminum, and the second metal-containing layer includes titanium nitride. In an embodiment, replacing the polymer layer with the dielectric layer includes removing the polymer layer by exposing surfaces of the polymer layer to water or a water-based solution having a pH level that is equal to or higher than 7; and forming the dielectric layer over the top surfaces of the lower gate electrode.

In accordance with an embodiment, a semiconductor device includes a plurality of first nanostructures, the plurality of first nanostructures extending between first source/drain regions; a plurality of second nanostructures over the plurality of first nanostructures, the plurality of second nanostructures extending between second source/drain regions; an isolation structure between the plurality of first nanostructures and the plurality of second nanostructures; a first gate stack around the plurality of first nanostructures; an isolation layer disposed on top surfaces of the first gate stack and adjacent to sidewalls of the isolation structure; and a second gate stack over the isolation layer, the isolation structure, and the first gate stack, the second gate stack being disposed around the plurality of second nanostructures, where the second gate stack includes; a first metal-containing layer around a second nanostructure of the plurality of second nanostructures; a second metal-containing layer over the first metal-containing layer and around the second nanostructure of the plurality of second nanostructures; and a first gate electrode layer over the first metal-containing layer and the second metal-containing layer, where bottom surfaces of the first metal-containing layer and the second metal-containing layer are in contact with the isolation layer. In an embodiment, the first metal-containing layer includes titanium aluminum, and the second metal-containing layer includes titanium nitride. In an embodiment, the isolation layer includes silicon oxide, silicon nitride, silicon oxynitride, silicon oxycarbonitride, or a combination thereof. In an embodiment, the isolation layer electrically isolates the first gate stack from the second gate stack. In an embodiment, the device further includes a gate dielectric layer that is disposed between a first sidewall of the isolation layer and a second sidewall of the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multi-layer stack over a semiconductor substrate, the multi-layer stack comprising alternating semiconductor nanostructures and dummy nanostructures;
forming lower source/drain regions, wherein lower semiconductor nanostructures of the semiconductor nanostructures extend between the lower source/drain regions;
forming upper source/drain regions over the lower source/drain regions, wherein upper semiconductor nanostructures of the semiconductor nanostructures extend between the upper source/drain regions;
removing the dummy nanostructures to form first openings between the lower semiconductor nanostructures, and second openings between the upper semiconductor nanostructures;
forming a gate dielectric layer around the lower semiconductor nanostructures and the upper semiconductor nanostructures;
forming a lower gate electrode around the lower semiconductor nanostructures and in the first openings;
selectively depositing a dummy layer over top surfaces of the lower gate electrode, the dummy layer comprising a first polymer; and
forming an upper gate electrode around the upper semiconductor nanostructures and in the second openings, wherein sidewalls of the upper gate electrode are in contact with a gate spacer, wherein a dielectric constant of the gate dielectric layer is greater than a dielectric constant of the gate spacer, wherein the upper gate electrode comprises a titanium-containing material.

2. The method of claim 1, wherein the first polymer is an anionic polymer.

3. The method of claim 2, wherein the anionic polymer comprises polyacrylic acid (PAA) or polyvinyl alcohol (PVA).

4. The method of claim 2, wherein the dummy layer also comprises a second polymer, and wherein the second polymer is a nonionic polymer.

5. The method of claim 4, wherein the nonionic polymer comprises polyacrylamide, polyethylene glycol, polystyrene sulfonate, or polyvinyl pyrrolidone.

6. The method of claim 1, wherein forming the upper gate electrode further comprises:
forming a first metal-containing layer around the upper semiconductor nanostructures and in the second openings;
forming a second metal-containing layer around the first metal-containing layer and in the second openings; and
depositing an upper gate electrode layer over the lower gate electrode, the first metal-containing layer, and the second metal-containing layer.

7. The method of claim 6, further comprising:
removing the dummy layer by exposing surfaces of the dummy layer to water or a water-based solution having a pH level that is equal to or higher than 7; and
forming a dielectric layer over the top surfaces of the lower gate electrode.

8. The method of claim 7, wherein the first metal-containing layer comprises titanium aluminum, and the second metal-containing layer comprises titanium nitride.

9. A method comprising:
forming a multi-layer stack over a semiconductor substrate, the multi-layer stack comprising alternating semiconductor layers and dummy layers;
patterning the multi-layer stack to form a fin, wherein the fin comprises alternating semiconductor nanostructures and dummy nanostructures, the semiconductor nanostructures defined from the semiconductor layers, and the dummy nanostructures defined from the dummy layers;
forming lower source/drain regions, wherein lower semiconductor nanostructures of the semiconductor nanostructures extend between the lower source/drain regions;
forming upper source/drain regions over the lower source/drain regions, wherein upper semiconductor nanostructures of the semiconductor nanostructures extend between the upper source/drain regions;
removing the dummy nanostructures to form first openings between the lower semiconductor nanostructures, and second openings between the upper semiconductor nanostructures;
forming a lower gate electrode around the lower semiconductor nanostructures and in the first openings;
selectively depositing a polymer layer over top surfaces of the lower gate electrode, wherein the polymer layer comprises a first polymer;
selectively forming a first metal-containing layer around the upper semiconductor nanostructures and in the second openings;
replacing the polymer layer with a dielectric layer; and
depositing an upper gate electrode layer over the first metal-containing layer, the dielectric layer, and the lower gate electrode.

10. The method of claim 9, wherein the first polymer is an anionic polymer that includes polyacrylic acid (PAA) or polyvinyl alcohol (PVA).

11. The method of claim 10, wherein the polymer layer also comprises a second polymer, and wherein the second polymer is a nonionic polymer.

12. The method of claim 11, wherein the nonionic polymer comprises polyacrylamide, polyethylene glycol, polystyrene sulfonate, or polyvinyl pyrrolidone.

13. The method of claim 9, further comprising:
selectively forming a second metal-containing layer around the first metal-containing layer, around the upper semiconductor nanostructures, and in the second openings.

14. The method of claim 13, wherein the first metal-containing layer comprises titanium aluminum, and the second metal-containing layer comprises titanium nitride.

15. The method of claim 9, wherein replacing the polymer layer with the dielectric layer comprises:
removing the polymer layer by exposing surfaces of the polymer layer to water or a water-based solution having a pH level that is equal to or higher than 7; and
forming the dielectric layer over the top surfaces of the lower gate electrode.

16. A semiconductor device comprising:
a plurality of first nanostructures, the plurality of first nanostructures extending between first source/drain regions;
a plurality of second nanostructures over the plurality of first nanostructures, the plurality of second nanostructures extending between second source/drain regions;
an isolation structure between the plurality of first nanostructures and the plurality of second nanostructures;
a first gate stack around the plurality of first nanostructures;
an isolation layer disposed on top surfaces of the first gate stack and adjacent to sidewalls of the isolation structure; and
a second gate stack over the isolation layer, the isolation structure, and the first gate stack, the second gate stack being disposed around the plurality of second nanostructures, wherein the second gate stack comprises;
a first metal-containing layer around a second nanostructure of the plurality of second nanostructures;
a second metal-containing layer over the first metal-containing layer and around the second nanostructure of the plurality of second nanostructures; and
a first gate electrode layer over the first metal-containing layer and the second metal-containing layer, wherein bottom surfaces of the first metal-containing layer and the second metal-containing layer are in contact with the isolation layer.

17. The semiconductor device of claim 16, wherein the first metal-containing layer comprises titanium aluminum, and the second metal-containing layer comprises titanium nitride.

18. The semiconductor device of claim 16, wherein the isolation layer comprises silicon oxide, silicon nitride, silicon oxynitride, silicon oxycarbonitride, or a combination thereof.

19. The semiconductor device of claim 16, wherein the isolation layer electrically isolates the first gate stack from the second gate stack.

20. The semiconductor device of claim 16, further comprising a gate dielectric layer that is disposed between a first sidewall of the isolation layer and a second sidewall of the isolation structure.
